(19) United States
(12) Patent Application Publication
(10) Pub. No.: US 2005/0064676 A1
(43) Pub. Date: Mar. 24, 2005

(54) Method of forming alignment mark

(75) Inventors: Akihiro Tobioka, Tokyo (JP); Naohisa Tamada, Tokyo (JP)

Correspondence Address: MCDERMOTT, WILL & EMERY, 600 13th Street, N.W., WASHINGTON, DC, 20005-3096, US

(73) Assignee: RENESAS TECHNOLOGY CORP

(21) Appl. No.: 10/944,781

(22) Filed: Sep. 21, 2004

(30) Foreign Application Priority Data
Sep. 24, 2003 (JP) JP2003-331283

(51) Int. Cl. H01L 21/4763

(52) U.S. Cl. 438/401; 438/629

(57) ABSTRACT

In a first step, first trenches are formed to constitute alignment marks. In a second step, second trenches are formed, and the first and second trenches are filled with metal. When detecting alignment marks, the second trenches filled with metal prevent the position of the first trenches from being detected. In a third step, third trenches of the same shape as the first trenches are formed. In a fourth step, fourth trenches are formed, and the third and fourth trenches are filled with metal. When detecting alignment marks, the fourth trenches filled with metal prevent the position of the third trenches formed in a lower layer from being detected. The third and fourth steps are repeated with an increase in the number of stacked layers. Consequently, influences caused by detection of alignment marks formed in a lower layer are reduced while controlling an increase in the area occupied by alignment marks.

### BACKGROUND OF THE INVENTION

1. Field of the Invention

The present invention relates to a method of forming an alignment mark, and is applicable to, for example, alignment when exposing a pattern in a lithography process.

2. Description of the Background Art

In the manufacture of semiconductor devices, alignment marks have conventionally been formed for aligning patterns in a lithography process. To control an increase in the area occupied by alignment marks, the alignment marks have been so formed as to conform with those already formed on a target (cf. Japanese Patent Application Laid-Open No. 2002-25888).

Japanese Patent Application Laid-Open No. 10-150085 (1988) discloses a technique in which alignment marks having a greater size than those formed in a lower layer are used for a resist pattern.

However, it has been difficult to accurately align alignment marks of the same shape, resulting in misalignment. When detecting the position of alignment marks exposed at a surface, the position of alignment marks formed in a lower layer is also detected through an insulating layer and a resist. Therefore, it has been difficult to define the position of the alignment marks exposed at the surface.

### SUMMARY OF THE INVENTION

An object of the present invention is to reduce influences caused by an alignment mark formed in a lower layer when detecting an alignment mark formed in an upper layer, while controlling an increase in the area occupied by the alignment marks.

According to a first aspect of the present invention, a method of forming an alignment mark includes the steps (a) and (b). The step (a) is to form a first pattern and a first alignment mark in parallel in an insulating layer. The step (b) is to form a second pattern and a second alignment mark in parallel in the insulating layer after the step (a). The second alignment mark covers the first alignment mark in the insulating layer in a first predetermined position.

An increase in the area for forming the alignment marks is controlled. Further, the second alignment mark covers the first alignment mark, so that detection of the first alignment mark is prevented while the second alignment mark is detected.

According to a second aspect of the invention, a method of forming an alignment mark includes the steps (a) to (c). The step (a) is to form a first pattern and a first alignment mark in parallel in a first insulating layer. The step (b) is to form a second insulating layer to cover the first insulating layer and the first alignment mark. The step (c) is to form a second pattern and a second alignment mark in parallel in the second insulating layer. The second alignment mark is located inside the first alignment mark in a predetermined position.

An increase in the area for forming the alignment marks is controlled. Further, even when the first alignment mark is detected when detecting the second alignment mark, influences caused by the first alignment mark are reduced since the positional relationship between the first and second alignment marks is clear.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1A to 1C are a conceptual sectional view, a top view and a waveform chart, respectively, for describing a first preferred embodiment of the present invention;

FIGS. 2A to 2C are a conceptual sectional view, a top view and a waveform chart, respectively, for describing the first preferred embodiment;

FIGS. 3A to 3C are a conceptual sectional view, a top view and a waveform chart, respectively, for describing the first preferred embodiment;

FIGS. 4A to 4C are a conceptual sectional view, a top view and a waveform chart, respectively, for describing the first preferred embodiment;

FIGS. 5A to 5C are a conceptual sectional view, a top view and a waveform chart, respectively, for describing a second preferred embodiment of the invention;

FIGS. 6A to 6C are a conceptual sectional view, a top view and a waveform chart, respectively, for describing the second preferred embodiment;

FIGS. 7A and 7B are a conceptual sectional view and a top view, respectively, for describing a third preferred embodiment of the invention;

FIGS. 8A and 8B are a conceptual sectional view and a top view, respectively, for describing the third preferred embodiment;

FIGS. 9A and 9B are a conceptual sectional view and a top view, respectively, for describing the third preferred embodiment; and

FIGS. 10A and 10B are a conceptual sectional view and a top view, respectively, for describing the third preferred embodiment.

### DESCRIPTION OF THE PREFERRED EMBODIMENTS

### First Preferred Embodiment

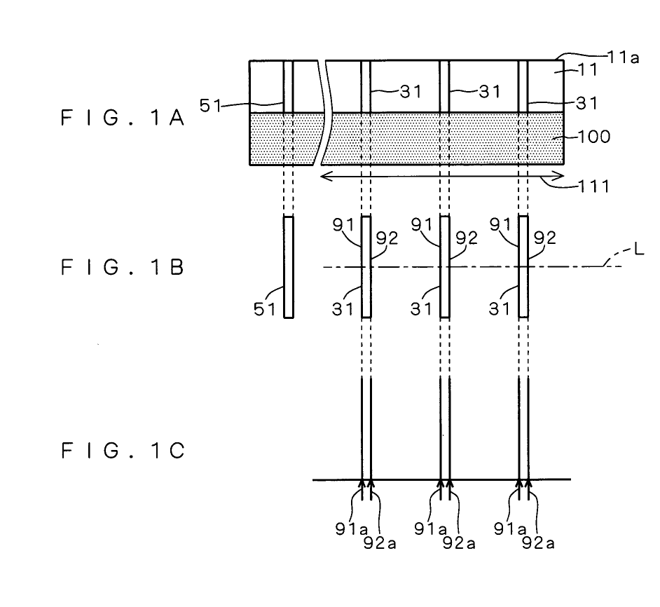

The present embodiment will describe a method of forming alignment marks in the case of employing a dual damascene method among damascene methods used for forming plugs and interconnect lines. Here, alignment marks formed by arranging rectangles in parallel to one another at a regular space shall be used. FIGS. 1A through 4C sequentially illustrate the steps of forming interconnect lines. FIGS. 1A, 2A, 3A and 4A are conceptual sectional views of alignment marks as formed, FIGS. 1B, 2B, 3B and 4B are top views of alignment marks as formed, and FIGS. 1C, 2C, 3C and 4C conceptually illustrate one-dimensional waveforms obtained when detecting the position of alignment marks by image processing.

In a first step, an insulating layer 11 is formed on a substrate 100. Then, trenches 31 to serve as alignment marks are formed in a region 111 by lithography and etching. Formation of the trenches 31 is conducted in parallel with that of a hole 51. The hole 51 is a via hole formed in the insulating layer 11, and is used for forming a first plug to be connected to a first interconnect line which will be described later (FIG. 1A). Each of the plug and interconnect line can be considered as a pattern. This applies throughout the present specification.

Next, the position of the trenches 31 is detected by an image processor from the side opposite to the substrate 100, i.e., at a surface 11a of the insulating layer 11. FIG. 1C shows a waveform detected by scanning the trenches 31 along a scanning line L. Straight lines 91 and 92 in pair constitute a rectangle presented by each of the trenches 31 at the surface 11a and cross the scanning line L. Peak positions 91a and 92a of the waveform correspond to the positions of the lines 91 and 92, respectively (FIG. 1B).

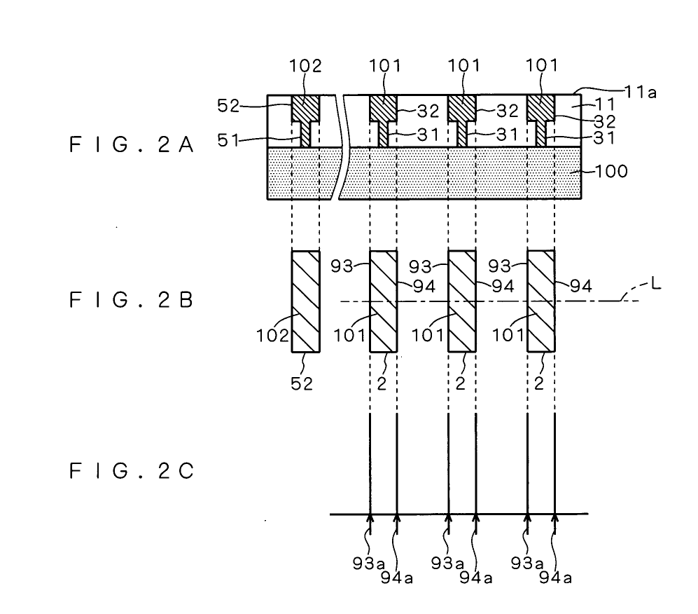

In a second step, the position of a mask pattern to be used in a subsequent lithography step is determined with reference to the peak positions 91a and 92a. Thereafter, exposure and etching is carried out using the mask pattern, thereby forming trenches 32 for alignment marks in the insulating layer 11 on the surface 11a side. Straight lines 93 and 94 in pair constitute a rectangle presented by each of the trenches 32 at the surface 11a. The lines 93 and 94 of a trench 32 crossing the scanning line L are arranged so as not either to locate between the lines 91 and 92 that constitute a trench 31 communicating to the trench 32 or to overlap the lines 91 and 92, respectively. Formation of the trenches 32 is conducted in parallel with that of a hole 52 to be used for forming the first interconnect line (FIGS. 2A and 2B). Then, metal burying is carried out, whereby the lines 93 and 94 in pair constitute a rectangle presented by an alignment mark 2 at the surface 11a.

More specifically, the holes 51 and 52 are filled with a metal 102 to form the first plug and first interconnect line, respectively. In parallel with this, the trenches 31 and 32 are filled with a metal 101. Then, the trenches 32 filled with the metal 101 become alignment marks 2 and are exposed at the surface 11a.

Next, the position of the alignment marks 2 is detected at the surface 11a. FIG. 2C shows the waveform detected by scanning the alignment marks 2 along the scanning line L. When detecting the position of the alignment marks 2, the alignment marks 2 themselves filled with the metal 101 prevent the trenches 31 from being detected. That is, only the position of the alignment marks 2 is detected. Accordingly, only the positions of the lines 93 and 94 are detected as peak positions 93a and 94a of the waveform.

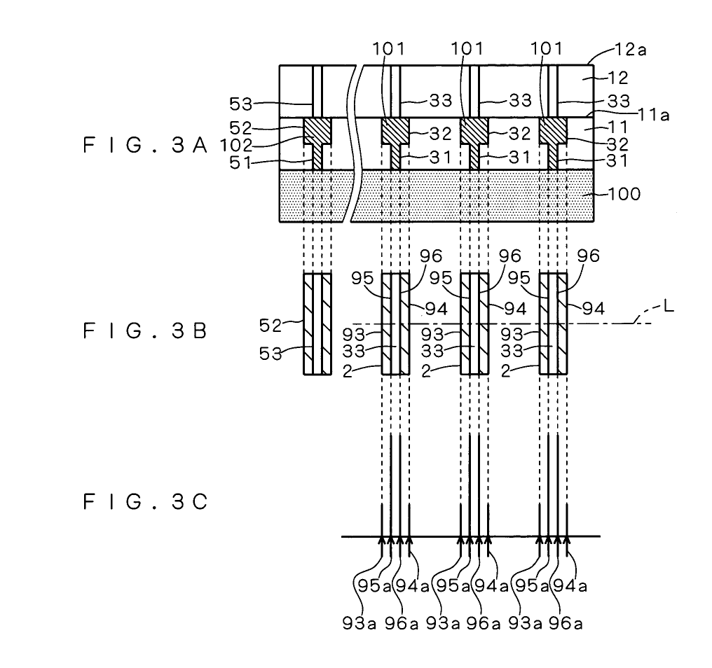

In a third step, an insulating layer 12 is formed over the insulating layer 11. Then, the position of a mask pattern to be used in a subsequent lithography step is determined with reference to the peak positions 93a and 94a. Thereafter, exposure and etching is carried out using the mask pattern, thereby forming trenches 33 for alignment marks in the insulating layer 12 on the alignment marks 2. Straight lines 95 and 96 in pair constitute a rectangle presented by each of the trenches 33 at a surface 12a of the insulating layer 12. The lines 95 and 96 of a trench 33 crossing the scanning line L are arranged so as to locate between the lines 93 and 94 that constitute a trench 32 communicating to the trench 33 and not to overlap the lines 93 and 94, respectively. The trenches 33 may be of the same size as the trenches 31, for example. Formation of the trenches 33 is conducted in parallel with that of a hole 53. The hole 53 is a via hole formed in the insulating layer 12, and is used for forming a second plug for connecting a second interconnect line which will be described later and the above-mentioned first interconnect line (FIGS. 3A and 3B).

Next, the position of the trenches 33 is detected at the surface 12a. At this time, the position of the alignment marks 2 formed in the lower layer is also detected through the insulating layer 12, because the lines 95 and 96 are located inside the alignment mark 2. FIG. 3C shows the waveform detected by scanning the trenches 33 along the scanning line L. Peak positions 95a and 96a of high strength respectively correspond to the positions of the lines 95 and 96 crossing the scanning line L. The peak positions 93a and 94a of low strength respectively correspond to the lines 93 and 94 constituting each of the alignment marks 2.

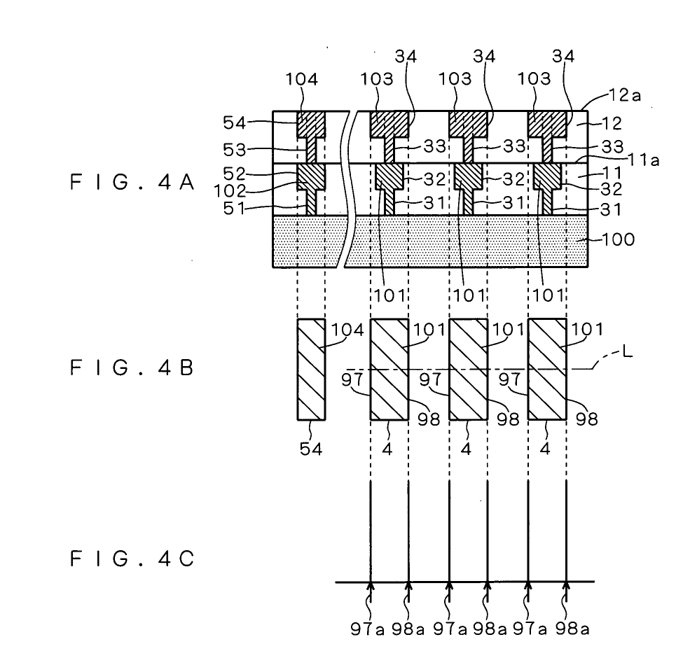

In a fourth step, the position of a mask pattern to be used in a subsequent lithography step is determined with reference to the peak positions 95a and 96a. Thereafter, exposure and etching is carried out using the mask pattern, thereby forming trenches 34 for alignment marks in the insulating layer 12 on the surface 12a side. Straight lines 97 and 98 in pair constitute a rectangle presented by each of the trenches 34 at the surface 11a. The lines 97 and 98 of a trench 34 crossing the scanning line L are arranged so as not either to locate between the lines 93 and 94 that constitute a trench 32 communicating to the trench 34 or to overlap the lines 93 and 94, respectively. Formation of the trenches 34 is conducted in parallel with that of a hole 54 to be used for forming the second interconnect line (FIGS. 4A and 4B). Then, metal burying is carried out, whereby the lines 97 and 98 in pair constitute a rectangle presented by an alignment mark 4 at the surface 12a.

More specifically, the holes 53 and 54 are filled with a metal 104 to form the second plug and second interconnect line, respectively. In parallel with this, the trenches 33 and 34 are filled with a metal 103. Then, the trenches 34 filled with the metal 103 become alignment marks 4 and are exposed at the surface 12a.

Next, the position of the alignment marks 4 is detected at the surface 12a. FIG. 4C shows the waveform detected by scanning the alignment marks 4 along the scanning line L. When detecting the position of the alignment marks 4, the alignment marks 4 themselves filled with the metal 103 prevent the position of the alignment marks 2 and trenches 33 from being detected. Accordingly, only the positions of the lines 97 and 98 are detected as peak positions 97a and 98a of the waveform.

Thereafter, the third and fourth steps are repeated, so that alignment marks are formed in parallel with formation of a plug and an interconnect line.

Through the above-described method of forming alignment marks, a region in which alignment marks are to be formed can be limited to a certain region regardless of the number of stacked insulating layers. Further, when detecting the position of alignment marks, the position of alignment marks formed in a lower layer is not detected.

Although the position of alignment marks in a lower layer is detected as mentioned in the description of the third step, making clear the positional relationship between alignment marks present in the lower layer and alignment marks desired to be detected can reduce influences caused by the alignment marks present in the lower layer.

The invention of the present embodiment is also applicable to a single damascene method. That is, an interconnect line and a plug are formed in each layer, and in parallel with this, alignment marks are formed. In this case, the waveforms illustrated in FIGS. 1C, 2C, 3C and 4C are also detected.

### Second Preferred Embodiment

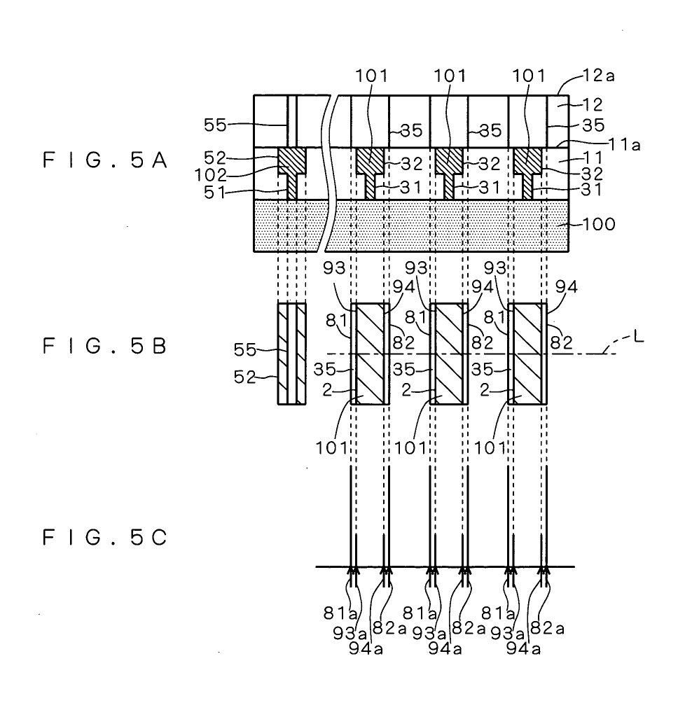

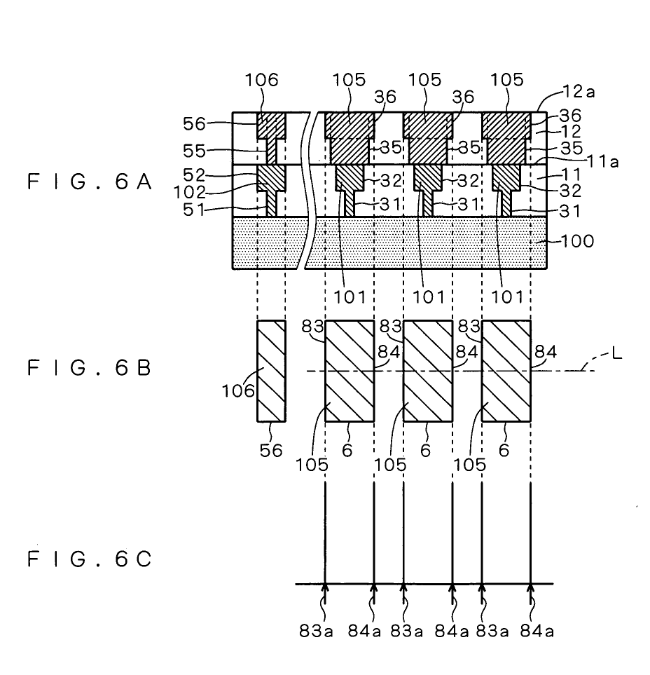

The present embodiment will describe a method of forming alignment marks different from that of the first preferred embodiment with respect to the third step (FIGS. 3A to 3C) and fourth step (FIGS. 4A to 4C). FIGS. 5A through 6C sequentially illustrate the steps of forming a second plug and a second interconnect line. FIGS. 5A and 6A are conceptual sectional views of alignment marks as formed, FIGS. 5B and 6B are top views of alignment marks as formed, and FIGS. 5C and 6C conceptually illustrate one-dimensional waveforms obtained when detecting the position of alignment marks by image processing.

In a third step, the insulating layer 12 is formed over the insulating layer 11, and the position of a mask pattern to be used in a subsequent lithography step is determined with reference to the peak positions 93a and 94a. Thereafter, exposure and etching is carried out using the mask pattern, thereby forming trenches 35 to serve as alignment marks in the insulating layer 12 over the alignment marks 2. Straight lines 81 and 82 in pair constitute a rectangle presented by each of the trenches 35 at the surface 12a of the insulating layer 12. The lines 81 and 82 of a trench 35 crossing the scanning line L are arranged so as not either to locate between the lines 93 and 94 that constitute a trench 32 communicating to the trench 35 or to overlap the lines 93 and 94, respectively. Formation of the trenches 35 is conducted in parallel with that of a hole 55. The hole 55 is a via hole formed in the insulating layer 12, and is used for forming the second plug for connecting the second interconnect line which will be described later and the first interconnect line formed in the hole 52 (FIGS. 5A and 5B).

Next, the position of the trenches 35 is detected at the surface 12a. At this time, the alignment marks 2 are exposed at the surface 11a which forms the bottom of each of the trenches 35, and therefore, the position of the alignment marks 2 is also detected. FIG. 5C shows the waveform detected by scanning the trenches 35 along the scanning line L. Peak positions 81a and 82a of high strength respectively correspond to the positions of the lines 81 and 82 crossing the scanning line L. The peak positions 93a and 94a of low strength respectively correspond to the lines 93 and 94 constituting each of the alignment marks 2.

In a fourth step, the position of a mask pattern is determined with reference to the peak positions 81a and 82a. Thereafter, exposure and etching is carried out using the mask pattern, thereby forming trenches 36 for alignment marks in the insulating layer 12 on the surface 12a side. Straight lines 83 and 84 in pair constitute a rectangle presented by each of the trenches 36 at the surface 12a. The lines 83 and 84 of a trench 36 crossing the scanning line L are arranged so as not either to locate between the lines 81 and 82 that constitute a trench 35 communicating to the trench 36 or to overlap the lines 81 and 82, respectively. Formation of the trenches 36 is conducted in parallel with that of a hole 56 to be used for forming the second interconnect line (FIGS. 6A and 6B). Then, metal burying is carried out, whereby the lines 83 and 84 in pair constitute a rectangle presented by an alignment mark 6 at the surface 12a.

More specifically, the holes 55 and 56 are filled with a metal 106 to form the second plug and second interconnect line, respectively. In parallel with this, the trenches 35 and 36 are filled with a metal 105. Then, the trenches 36 filled with the metal 105 become alignment marks 6 and are exposed at the surface 12a.

Next, the position of the alignment marks 6 is detected at the surface 12a. FIG. 6C shows the waveform detected by scanning the alignment marks 6 along the scanning line L. When detecting the position of the alignment marks 6, the alignment marks 6 themselves filled with the metal 105 prevent the position of the alignment marks 2 and trenches 35 from being detected. Accordingly, only the positions of the lines 83 and 84 are detected as peak positions 83a and 84a of the waveform.

Thereafter, the above-described third and fourth steps are repeated, so that alignment marks are formed in parallel with formation of a plug and an interconnect line. This technique is also applicable to the single damascene method.

Through the method of forming alignment marks according to the present embodiment, similar effects to those achieved by the first preferred embodiment can be obtained. In the first and second preferred embodiments, the size relationship between trenches for forming alignment marks shall be determined in each step of forming a pair of a plug and an interconnect line which is in contact with the plug on the side opposite to the substrate, but trenches for forming alignment marks have any size relationship between steps of forming different pairs of a plug and an interconnect line.

### Third Preferred Embodiment

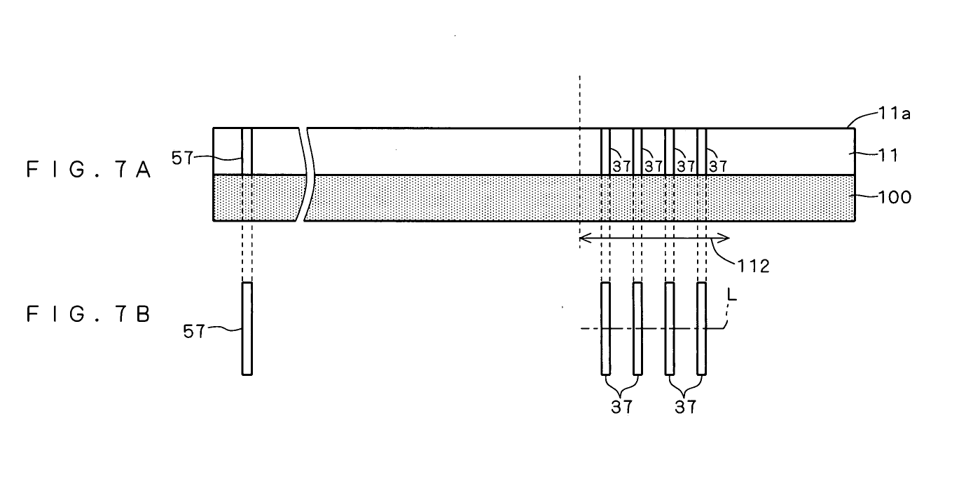

The present embodiment will describe a method of forming alignment marks in which alignment marks are formed in a region in parallel with formation of a via hole for forming a plug and alignment marks are formed in a separate region in parallel with formation of a trench for forming an interconnect line. FIGS. 7A through 10B conceptually illustrate the method of forming alignment marks according to the present embodiment. FIGS. 7A, 8A, 9A and 10A are sectional views, and FIGS. 7B, 8B, 9B and 10B are top views.

In a first step, the insulating layer 11 is formed over the substrate 100. Trenches 37 to serve as alignment marks are formed in a region 112 for forming alignment marks by lithography and etching. Formation of the trenches 37 is conducted in parallel with that of a hole 57. The hole 57 is a via hole formed in the insulating layer 11, and is used for forming a first plug to be connected to a first interconnect line which will be described later (FIG. 7A). Then, the position of the trenches 37 is detected at the surface 11a along the scanning line L (FIG. 7B).

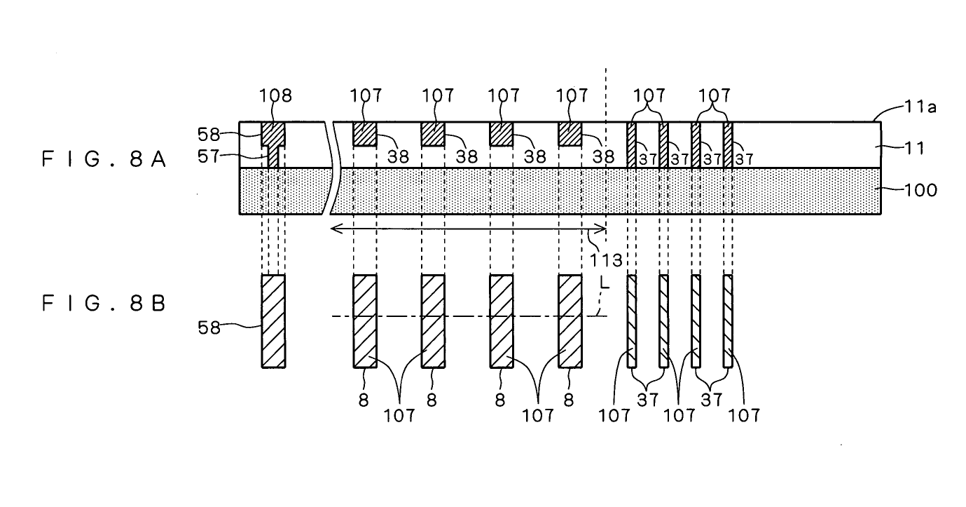

In a second step, the position of a mask pattern is determined with reference to the position of the trenches 37. Thereafter, exposure and etching is carried out using the mask pattern, thereby forming trenches 38 for alignment marks in a region 113 for forming alignment marks in the insulating layer 11. The region 113 is different from the region 112. Formation of the trenches 38 is conducted in parallel with that of a hole 58 to be used for forming the first interconnect line (FIG. 8A).

Then, the holes 57 and 58 are filled with a metal 108 to form the first plug and first interconnect line, respectively. In parallel, the trenches 37 and 38 are filled with a metal 107. Then, the trenches 38 filled with the metal 107 become alignment marks 8 and are exposed at the surface 11a. The position of the alignment marks 8 is detected at the surface 11a along the scanning line L (FIG. 8B).

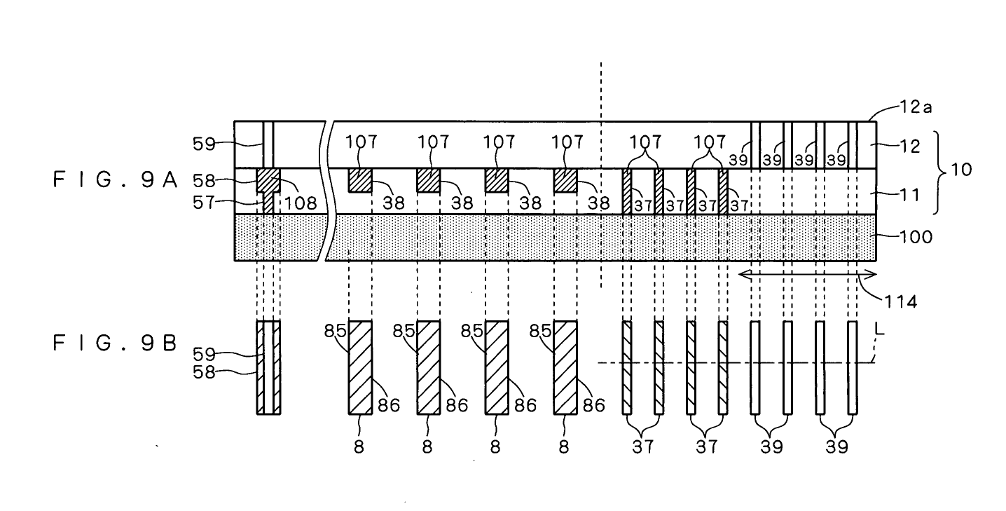

In a third step, the insulating layer 12 is formed over the insulating layer 11. Then, the position of a mask pattern is determined with reference to the alignment marks 8. Thereafter, exposure and etching is carried out using the mask pattern, thereby forming trenches 39 to serve as alignment marks in a region 114 for forming alignment marks in the insulating layer 12. The region 114 is different from the regions 112 and 113. Formation of the trenches 39 is conducted in parallel with that of a hole 59. The hole 59 is a via hole formed in the insulating layer 12, and is used for forming a second plug for connecting the second interconnect line which will be described later and the above-mentioned first interconnect line (FIG. 9A). Then, the position of the trenches 39 is detected at the surface 12a along the scanning line L (FIG. 9B).

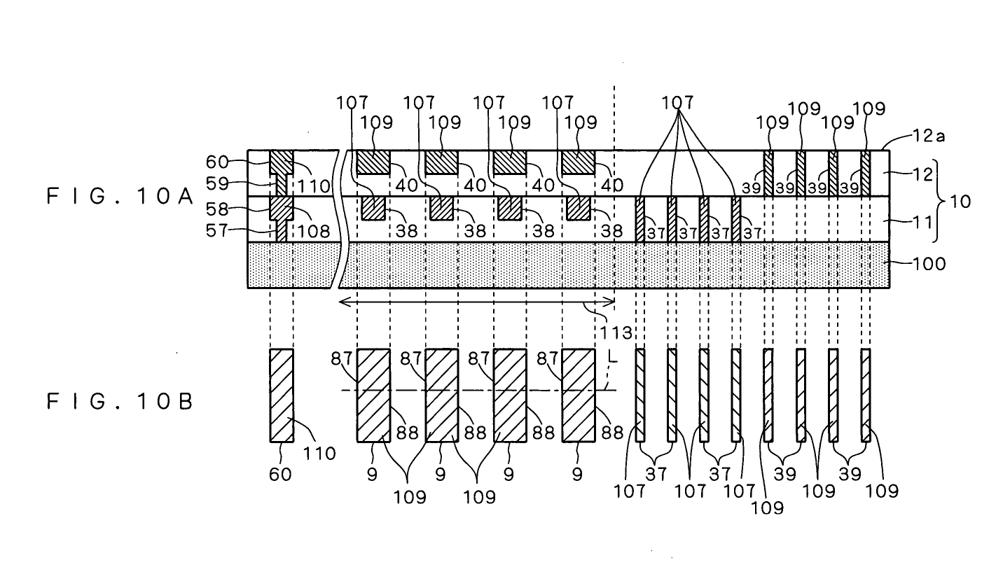

In a fourth step, the position of a mask pattern is determined with reference to the position of the trenches 39. Thereafter, exposure and etching is carried out using the mask pattern, thereby forming trenches 40 for alignment marks in the region 113 in the insulating layer 12 over the alignment marks 8. Straight lines 87 and 88 in pair constitute a rectangle presented by each of the trenches 40 at the surface 12a. The lines 87 and 88 of a trench 40 are arranged so as not either to locate between lines 85 and 86 (FIG. 9B) that constitute an alignment mark 8 communicating to the trench 40 or to overlap the lines 85 and 86, respectively. Formation of the trenches 40 is conducted in parallel with that of a hole 60 to be used for forming the second interconnect line (FIG. 10A).

As described, alignment of the mask pattern to be used for forming the trenches 40 for alignment marks is conducted with reference to the position of the trenches 39 formed in the region 114. When detecting the position of the trenches 39, the position of the trenches 37 is detected in the region 112 but does not appear in the region 114, which therefore causes no problem.

Then, the holes 59 and 60 are filled with a metal 110 to form the second plug and second interconnect line, respectively. In parallel with this, the trenches 39 and 40 are filled with a metal 109. Accordingly, the trenches 40 filled with the metal 109 become alignment marks 9 and are exposed at the surface 12a. The position of the alignment marks 9 is detected at the surface 12a along the scanning line L (FIG. 10B).

The insulating layers 11 and 12 may be considered as one insulating layer 10 in combination. That is, the insulating layer 12 covers the insulating layer 11 and alignment marks 8, and constitutes the insulating layer 10 in combination with the insulating layer 11. The alignment marks 8 can be considered as being formed within the insulating layer 10.

Through the above-described method of forming alignment marks, a region in which alignment marks are formed to overlap alignment marks formed underneath in parallel with formation of trenches for interconnect lines can be limited to the region 113. In the region 113, when detecting the alignment marks 9 at the surface 12a, the position of the alignment marks 8 formed in the lower insulating layer 11 can be prevented from being detected. Further, in the first to third steps, only the position of rectangles represented at the surface is detected while the position of alignment marks in a lower layer is not detected.

Furthermore, the size relationship between the trenches 38 and 40 for forming the alignment marks 8 and 9, respectively, formed in the region 113 shall be determined, but trenches 37 and 39 formed in the regions 112 and 114, respectively, may have any size relationship with the trenches 38 and 40. Similarly, the trenches 37 and 39, formed in different regions, may have any size relationship with each other.

The present embodiment is also applicable to the case of forming the trenches 37 and 39 in the same region in the first and third steps. In this case, it is preferable to determine the size relationship between the trenches 37 and 39. However, the trenches 37 and 39 may have any size relationship with the trenches 38 and 40.

While the invention has been shown and described in detail, the foregoing description is in all aspects illustrative and not restrictive. It is therefore understood that numerous modifications and variations can be devised without departing from the scope of the invention.

1. A method of forming an alignment mark, comprising the steps of:
(a) forming a first pattern and a first alignment mark in parallel in an insulating layer; and
(b) forming a second pattern and a second alignment mark in parallel in said insulating layer after said step (a), wherein
said second alignment mark covers said first alignment mark in said insulating layer in a first predetermined position.

2. The method according to claim 1, wherein
said second alignment mark is detectable in said first predetermined position.

3. The method according to claim 1, wherein
said first pattern is an interconnect line.

4. The method according to claim 1, wherein
said second pattern is a plug.

5. The method according to claim 1, wherein
said insulating layer includes a first insulating layer and a second insulating layer stacked on said first insulating layer, and
said steps (a) and (b) are conducted in said first insulating layer,
said method further comprising the steps of:
(c) forming said second insulating layer to cover said first insulating layer and said second alignment mark; and
(d) forming a third pattern and a third alignment mark in parallel in said second insulating layer, wherein
said third alignment mark covers said second alignment mark in a second predetermined position.

6. The method according to claim 5, wherein
said third alignment mark is detectable in said second predetermined position.

7. The method according to claim 5, wherein
said third pattern is an interconnect line.

8. The method according to claim 1, wherein
said insulating layer includes a first insulating layer and a second insulating layer stacked on said first insulating layer, and
said steps (a) and (b) are conducted in said first insulating layer,
said method further comprising the steps of:
(c) forming said second insulating layer to cover said first insulating layer and said second alignment mark; and
(d) forming a third pattern and a third alignment mark in parallel in said second insulating layer, wherein
said third alignment mark is located inside said second alignment mark in a second predetermined position.

9. The method according to claim 8, wherein
said third alignment mark is detectable in said second predetermined position.

10. The method according to claim 8, wherein
said third pattern is an interconnect line.

11. The method according to claim 1, wherein
said insulating layer includes a first insulating layer and a second insulating layer stacked on said first insulating layer,
said step (a) includes the steps of:
(a-1) forming said first pattern and said first alignment mark in said first insulating layer; and
(a-2) forming said second insulating layer to cover said first insulating layer and said first alignment mark, and
said second pattern and said second alignment mark are formed in said second insulating layer in said step (b).

12. The method according to claim 11, wherein
said second alignment mark is detectable in said first predetermined position.

13. The method according to claim 1 1, wherein
said first pattern is an interconnect line.

14. The method according to claim 11, wherein
said second pattern is a plug.

15. A method of forming an alignment mark, comprising the steps of:
(a) forming a first pattern and a first alignment mark in parallel in a first insulating layer;
(b) forming a second insulating layer to cover said first insulating layer and said first alignment mark; and
(c) forming a second pattern and a second alignment mark in parallel in said second insulating layer, wherein
said second alignment mark is located inside said first alignment mark in a predetermined position.

16. The method according to claim 15, wherein
said second alignment mark is detectable in said predetermined position.

17. The method according to claim 15, wherein
said first pattern is an interconnect line.

18. The method according to claim 15, wherein
said second pattern is a plug.
